(19) United States
(12) Patent Application Publication
(10) Pub. No.: US 2004/0131970 A1
(43) Pub. Date: Jul. 8, 2004

(54) Photodefinable polymers for semiconductor applications

(76) Inventors: Robert P. Meagley, Hillsboro, OR (US); Michael D. Goodner, Hillsboro, OR (US)

Correspondence Address: Timothy N. Trop, TROP, PRUNER & HU, P.C., 8554 KATY FWY, STE 100, HOUSTON, TX, 77024-1841, US

(21) Appl. No.: 10/337,575

(22) Filed: Jan. 7, 2003

(51) Int. Cl. G03F 7/004

(52) U.S. Cl. 430/280.1; 522/71; 522/81; 522/83; 522/77; 430/283.1; 430/285.1; 430/270.1; 430/905; 430/910

(57) ABSTRACT

A polymer system for semiconductor applications may be formed by blending a filler material and a precursor for a photodefinable polymer. The filler may be chosen so as not to adversely affect the photodefinability of the resulting system and, in some embodiments, may improve the mechanical or chemical properties of the resulting system.

### BACKGROUND

This invention relates generally to the fabrication of integrated circuits.

In the fabrication of integrated circuits, it is desired to pattern various structures defined on a substrate. This patterning may involve the exposure of photodefinable layers to an energy source such as light or other radiation. The exposed layers react upon exposure and either become more or less easily removed.

Examples of applications for photodefinable materials in semiconductor fabrication include buffer coatings, dielectrics, thin film photoresists, dry film photoresists, underfill, epoxy materials, adhesives, and thermal interface materials.

Existing photodefinable semiconductor materials have less than optimal mechanical and chemical properties. For example, the modulus and chemical resistance of some photodefinable materials results in mechanical or chemical failure under certain circumstances.

Thus, there is a need for better ways to make photodefinable polymers for semiconductor applications.

### DETAILED DESCRIPTION

In accordance with one embodiment of the present invention, a photodefinable matrix may include a polymer or polymer precursor. Examples of polymers or polymer precursors for photodefinable matrixes include polyimide, polyimide precursors, polybenzoxazole (PBO), PBO precursors, polyacrylates, polymethacrylates, alicyclic polymers, polyolefins, benzocyclobutene, benzocyclobutene precursors, fluorinated derivatives of benzocyclobutene, polycarbonates, and epoxies. The precursor in an uncured state may be blended with filler and then cured to form a cross-linked polymer layer.

The filler contributes advantageous mechanical and chemical properties such as improved modulus or improved chemical resistance to the system. In addition, the filler advantageously adheres well to the matrix. Furthermore, a surface treatment may be applied to the filler to promote adhesion to the matrix material and/or to facilitate blending.

In some embodiments, the filler may have a relatively small particle size so as to be non-scattering to the radiation used to photodefine the resulting composite system. Thus, in some embodiments, the filler may have a particle size less than 100 nanometers and in other embodiments, the filler may have a particle size less than 20 nanometers.

Examples of suitable fillers include metal oxides, such as silica. Other filler materials may include clays, alumina, titania, zirconia, other inorganic oxides and salts, glass, ceramics, cross-linked and insoluble polymers, ash, carbon, metals, soluble polymers, biopolymers, organic, and inorganic fibers.

The use of metal oxide particles may be advantageous in some embodiments because metal oxides can contribute good chemical resistance to solvent-based strippers, increased transparency, and low coefficient of thermal expansion to the final formulation. In one embodiment, Zirconia particles approximately 13 nanometers in diameter may be incorporated into the system at from about 9 to about 20 percent by weight. In one example, the matrix polymer precursor may be PBO. In other embodiments, the filler may constitute from about 5 to about 80 percent by weight.

The resulting composite polymer system, including the inorganic filler and polymer, may be utilized as a buffer coating, an underfill material, a thick film photoresist, an interlayer dielectric material, an adhesive, or a thermal interface material, as examples.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
blending a photodefinable polymer precursor with a filler having a particle size of less than 100 nanometers.

2. The method of claim 1 including blending the photodefinable precursor with a filler having a particle size less than 20 nanometers.

3. The method of claim 1 including blending the photodefinable precursor with a filler having a surface treatment to promote adhesion to the polymer precursor.

4. The method of claim 1 including blending the photodefinable precursor with a filler having a surface treatment to facilitate blending of the filler into the polymer precursor.

5. The method of claim 1 including blending the photodefinable precursor with a filler in the form of metal oxide.

6. The method of claim 1 including curing the precursor after blending with a filler.

7. The method of claim 1 including blending the precursor with a filler so that the filler constitutes from about 9 to about 20 percent by weight.

8. The method of claim 1 including blending the precursor with a filler so that the filler constitutes from about 5 to about 80 percent by weight.

9. The method of claim 1 including forming a polymer from said blended precursor and filler.

10. A photodefinable polymer for semiconductor applications comprising:
a photodefinable resin; and
a filler material having a particle size of less than 100 nanometers.

11. The polymer of claim 10 wherein said filler material includes metal oxide.

12. The polymer of claim 10 wherein said filler material has a particle size of less than 20 nanometers.

13. The polymer of claim 10 wherein said filler material has a surface treatment to promote adhesion to the polymer precursor.

14. The method of claim 10 including blending the photodefinable precursor with a filler having a surface treatment to facilitate blending of the filler into the polymer precursor.

15. The polymer of claim 10 wherein said resin includes a constituent selected from the group including polybenzoxazole, polyacrylates, polymethacrylates, alicyclic polymers, polyolefins, benzocyclobutene, polycarbonates, and epoxies.

16. The polymer of claim 10 wherein said filler material comprises from about 9 to about 20 percent by weight.

17. The polymer of claim 10 wherein said filler material comprises from about 5 to about 80 percent by weight.

18. The polymer of claim 10 wherein said filler material is inorganic.

19. The polymer of claim 10 wherein said filler material is organic.

20. A photodefinable polymer for semiconductor applications comprising:
a photodefinable resin; and
a filler comprising about 9 to about 20 percent of the system, said filler having a particle size of less than 20 nanometers.

21. The polymer of claim 20 wherein said filler has a surface treatment to promote adhesion to the polymer precursor.

22. The polymer of claim 20 wherein said filler has a surface treatment to facilitate blending of the filler into the polymer precursor.

23. The polymer of claim 20 wherein said filler is a metal oxide.

24. A polymer precursor for semiconductor applications comprising:
a photodefinable polymer precursor; and
a filler material having a particle size of less than 100 nanometers.

25. The precursor of claim 24 wherein said filler material includes a metal oxide.

26. The precursor of claim 24 wherein said filler material has a particle size of less than 20 nanometers.

27. The precursor of claim 24 wherein said filler material has a surface treatment to promote adhesion to the polymer precursor.

28. The polymer of claim 24 wherein said filler has a surface treatment to facilitate blending of the filler into the polymer precursor.

29. The precursor of claim 24 wherein said filler material comprises about 9 to about 20 percent by weight.

30. An integrated circuit comprising:
a substrate; and
a photodefinable polymer formed on said substrate, said polymer including a photodefinable resin and a filler material having a particle size of less than 100 nanometers.

31. The circuit of claim 30 wherein said filler material includes a metal oxide.

32. The circuit of claim 30 wherein said filler material has a particle size of less than 20 nanometers.

33. The circuit of claim 30 wherein said filler material has a surface treatment to promote adhesion to the polymer precursor.

34. The polymer of claim 30 wherein said filler has a surface treatment to facilitate blending of the filler into the polymer precursor.

35. The circuit of claim 30 wherein said filler material comprises from about 9 to about 20 percent by weight.
